(19) United States
(12) Patent Application Publication
(10) Pub. No.: US 2007/0161258 A1
(43) Pub. Date: Jul. 12, 2007

(54) METHOD OF FABRICATING A SEMICONDUCTOR DEVICE HAVING A HYDROGEN SOURCE LAYER

(75) Inventors: Ki-Heum NAM, Seoul (KR); Chear-Yeon MUN, Gyeonggi-do (KR); Bo-Sung KIM, Gyeonggi-do, (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggid-do (KR)

(21) Appl. No.: 11/552,877

(22) Filed: Oct. 25, 2006

(30) Foreign Application Priority Data
Jan. 6, 2006 (KR) 2006-1875

(51) Int. Cl. H01L 21/31

(52) U.S. Cl. 438/783

(57) ABSTRACT

In an embodiment, a method of fabricating a semiconductor device having a hydrogen source layer includes forming an interlayer insulating layer on a semiconductor substrate. A hydrogen source layer is formed on the substrate having the interlayer insulating layer. A thermal annealing process is performed on the substrate having the hydrogen source layer such that hydrogen inside the hydrogen source layer is diffused to a surface of the semiconductor substrate. A conductive pattern is formed on the substrate having the thermally-treated hydrogen source layer. The conductive pattern may be a metal interconnection.

### CROSS-REFERENCE TO RELATED APPLICATION

This application claims priority from Korean Patent Application No. 10-2006-1875, filed on Jan. 06, 2006, the disclosure of which is hereby incorporated herein by reference in its entirety as if set forth fully herein.

### BACKGROUND

1. Technical Field

The present invention relates to a method of fabricating a semiconductor device, and more particularly, to a method of fabricating a semiconductor device having a hydrogen source layer.

2. Discussion of the Related Art

In a semiconductor device, a discrete device such as a metal oxide semiconductor field effect transistor (MOSFET) is often used as a switching device. On-current formed in a channel between a source and a drain of the MOSFET is a part of what determines an operating speed of the semiconductor device.

Much research is aimed at scaling down the size of the MOSFET in accordance with high integration densities and high performances of state-of-the-art semiconductor devices. Scaling down the size of the MOSFET improves integration density and improves switching operating speed by reducing the size of the device, and improves a signal transfer speed by shortening a distance between devices.

However, as the MOSFET is scaled down, the device is increasingly influenced by the leakage current characteristics of the MOSFET. When an interface trap density of a gate insulating layer increases, a leakage current of the MOSFET may increase. The interface trap density of the gate insulating layer is related to structural defects of a silicon crystal structure, i.e., a cause of dangling bond. Silicon atoms may fail to form a complete crystallization bonding on a silicon interface bond with charge carriers in order to form a stable structure. Thus, the source/drain current flowing through the channel may effectively be charge carrier flow, causing current loss.

Generally, to cure dangling bonds remaining on the silicon interface, that is, the interface of the gate insulating layer of the MOSFET, a post-metal annealing process is carried out under a hydrogen ambient atmosphere at a temperature of about 450° C., at the final step prior to assembly and packaging processes of a semiconductor device. However, a semiconductor device may have a multi-level interconnection structure according to the high performance and the high density integration of a semiconductor device. Thus, if the post-metal anneal as described above is applied to the semiconductor device in the multi-level interconnection structure, the multi-level interconnection may be a barrier to the diffusion of hydrogen into the silicon interface. Then, there may be a limit to curing the dangling bonds on the silicon interface by the post-metal anneal. Further the post-metal anneal may cause a thermal stress on the multi-level interconnection.

As a method for improving the leakage current characteristics of the MOSFET, a method of supplying hydrogen to a silicon interface forming an incomplete bonding has been disclosed in U.S. Pat. No. 6,248,673 B1 entitled “HYDROGEN THERMAL ANNEALING METHOD FOR STABILIZING MICROELECTRONIC DEVICES” by Huang, et al. According to Huang, et al., a MOSFET is formed on a substrate, and an interlayer dielectric layer is formed to cover the MOSFET to be protected. In this case, the interlayer dielectric layer may be formed of a silicon oxide layer. A hydrogen annealing process is performed on the substrate having the interlayer dielectric layer under an ambient gas atmosphere that includes hydrogen. As a result, the hydrogen in the ambient gas atmosphere may be diffused into the substrate through the interlayer dielectric layer, bonding with silicon atoms of the incomplete crystallization interface. Thus, the MOSFET can be stabilized. However, when a high temperature process is performed during subsequent processes after the hydrogen anneal at the early step of forming the MOSFET, the hydrogen bonded with the silicon atoms of the crystallization interface may be separated from the atoms, and thus, the leakage current characteristics of the MOSFET may be deteriorated after all.

### SUMMARY

Therefore, embodiments provide a method of fabricating a semiconductor device having a hydrogen source layer.

In accordance with an exemplary embodiment, the method of fabricating a semiconductor device includes forming an interlayer insulating layer on a semiconductor substrate. A hydrogen source layer is formed on the substrate having the interlayer insulating layer. A thermal annealing process is performed on the substrate having the hydrogen source layer such that hydrogen inside the hydrogen source layer is diffused to a surface of the semiconductor substrate. A conductive pattern is formed on the substrate having the thermally-treated hydrogen source layer.

In exemplary embodiments, the hydrogen source layer may be formed of an insulating layer including hydrogen.

Further, the hydrogen source layer may include a silicon nitride layer. In this case, the silicon nitride layer may be formed of a plasma enhanced chemical vapor deposition (PECVD) nitride layer.

Further, the thermal annealing process may be performed at a temperature of about 350° C. to about 500° C.

Further, the thermal annealing process may be performed for a time of about 30 min. to about 300 min.

Further, the thermal annealing process may be performed using an ambient gas comprising nitrogen and/or hydrogen.

Further, the conductive pattern may be a metal interconnection.

Other embodiments provide a method of fabricating a semiconductor device capable of improving the leakage current characteristics of a MOS transistor. The method includes forming a MOS transistor on a semiconductor substrate. An interlayer insulating layer is formed on the substrate having the MOS transistor. A hydrogen source layer is formed on the interlayer insulating layer. A thermal annealing process is performed on the substrate having the hydrogen source layer such that hydrogen inside the hydrogen source layer is diffused to a surface of the semiconductor substrate. A lower metal interconnection is formed on the substrate having the hydrogen source layer.

In exemplary embodiments, forming the interlayer insulating layer may include forming a lower interlayer insulating layer on the substrate having the MOS transistor, and forming an upper interlayer insulating layer on the substrate having the lower interlayer insulating layer. Before forming the upper interlayer insulating layer, the method may further include forming a lower hydrogen source layer on the lower interlayer insulating layer. The lower hydrogen source layer may be formed of an insulating layer including hydrogen. Further, after forming the lower hydrogen source layer, the method may further include forming a conductive line on the substrate having the lower hydrogen source layer.

In exemplary embodiments, the method may further include forming an inter-metal insulating layer on the substrate having the lower metal interconnection, forming an upper metal interconnection on the inter-metal insulating layer, and forming a passivation layer on the substrate having the upper metal interconnection.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIGS. 1 through 3 are cross-sectional views illustrating a method of fabricating a semiconductor device according to some embodiments.

### DETAILED DESCRIPTION OF EXAMPLE EMBODIMENTS

The present invention will now be described more fully hereinafter with reference to the accompanying drawings, in which preferred embodiments of the invention are shown. This invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity. Like numbers refer to like elements throughout the specification.

FIGS. 1 through 3 are cross-sectional views illustrating a method of fabricating a semiconductor device according to embodiments.

Referring to the embodiment of FIG. 1, a semiconductor substrate 100 is prepared. The semiconductor substrate 100 may be a silicon substrate. An isolation layer 105 is formed in a predetermined portion of the semiconductor substrate 100, to confine an active region 105a. The isolation layer 105 may be a trench isolation layer. A MOS transistor 117 is formed on the active region 105a. Specifically, a gate insulating layer 107 is formed on the semiconductor substrate of the active region 105a, and a gate conductive layer may be formed on the substrate having the gate insulating layer 107. The gate conductive layer is patterned, thereby forming a gate electrode 109 crossing the active region 105a. Then, impurities are implanted into the active region 105a using the gate electrode 109 and the isolation layer 105 as ion implantation masks, thereby forming source/drain regions 115. Here, the gate insulating layer 107, the gate electrode 109, and the source/drain regions 115 may constitute a MOS transistor 117.

An interlayer insulating layer 136 is formed on the substrate having the MOS transistor 117. The interlayer insulating layer 136 may be formed of a silicon oxide layer. The interlayer insulating layer 136 may include a lower interlayer insulating layer 120 and an upper interlayer insulating layer 135, which are sequentially stacked. Specifically, the lower interlayer insulating layer 120 is formed on the substrate having the MOS transistor 117, and the upper interlayer insulating layer 135 is formed on the lower interlayer insulating layer 120, thereby forming the interlayer insulating layer 136, which are composed of the lower interlayer insulating layer 120 and the upper interlayer insulating layer 135.

A hydrogen source layer 140 is formed on the substrate having the interlayer insulating layer 136. The hydrogen source layer 140 may be formed of an insulating layer containing hydrogen, such as a silicon nitride layer containing hydrogen, for example. In this case, the silicon nitride layer may be a PECVD (plasma enhanced chemical vapor deposition) nitride layer using a PECVD method. The PECVD nitride layer may be formed using a silicon source gas and a nitrogen source gas as process gases. The silicon source gas may be a silane (SiH₄) gas, and the nitrogen source gas may be an ammonia (NH₃) gas, to name some examples.

Before the upper interlayer insulating layer 135 is formed subsequently to the formation of the lower interlayer insulating layer 120, a lower hydrogen source layer 125 may be formed on the lower interlayer insulating layer 120. The lower hydrogen source layer 125 may be formed of an insulating layer containing hydrogen, as in the case of the hydrogen source layer 140. For example, the lower hydrogen source layer 125 may be formed of a silicon nitride layer containing hydrogen using a PECVD method. Further, a conductive line 130 may be formed on the substrate having the lower hydrogen source layer 125. The conductive line 130 can function as a bit line electrically connected to one of the source and drain regions of the MOS transistor 117. That is, the gate electrode 109 may function as a word line, and the conductive line 130 may function as a bit line.

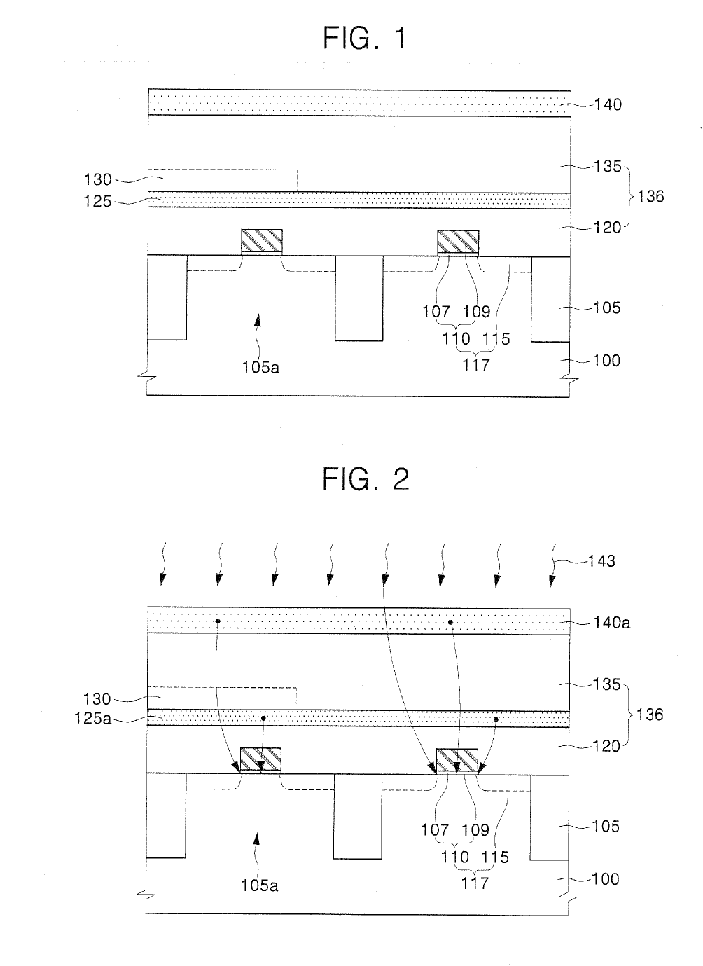

Referring to FIG. 2, a thermal annealing process 143 is performed on the substrate having the hydrogen source layer 140, to diffuse the hydrogen inside the hydrogen source layer 140. Thus, hydrogen atoms will be diffused to the surface of the semiconductor substrate 100. An example of conditions for which the thermal annealing process 143 may be performed includes temperatures of 350° C. to 500° C., for a time of 30 to 300 minutes, and in an ambient gas including nitrogen or hydrogen. That is, the thermal annealing process 143 may be performed using a nitrogen ambient, a hydrogen ambient, or a forming gas ambient. Here, the forming gas may be a mixing gas including nitrogen and hydrogen. For example, the forming gas may be composed of 95% of nitrogen and 5% of hydrogen.

The surface of the semiconductor substrate 100, where the hydrogen from inside the hydrogen source layer 140 reaches, may be an interface of the gate insulating layer 107. As a result, the interface trap sites of the gate insulating layer 107 are filled with the hydrogen from inside the hydrogen source layer 140, that is, hydrogen atoms, to significantly decrease an interface trap density of the gate insulating layer 107. Therefore, the leakage current characteristics of the MOS transistor 117 can be improved.

Furthermore, when the interlayer insulating layer 136 is composed of the lower interlayer insulating layer 120 and the upper interlayer insulating layer 135, which are sequentially stacked, and the lower hydrogen source layer 125 is formed between the lower interlayer insulating layer 120 and the upper interlayer insulating layer 135, the hydrogen from inside the lower hydrogen source layer 125 may also be diffused into the surface of the semiconductor substrate 100, that is, the interface of the gate insulating layer 107, during the thermal annealing process 143. Therefore, the leakage current characteristics of the MOS transistor 117 can be further improved.

In the thermal annealing process, subsequent to the hydrogen diffusion to the surface of the semiconductor substrate 100, the hydrogen source layer 140 and the lower hydrogen source layer 125 may be respectively defined as a thermally-treated hydrogen source layer 140a and a thermally-treated lower hydrogen source layer 125a.

When the thermal annealing process 143 is performed under an ambient gas that includes hydrogen, the hydrogen atoms may be diffused to and reach the surface of the semiconductor substrate 100 during the thermal annealing process 143. Therefore, the leakage current characteristics of the MOS transistor 117 can be further improved.

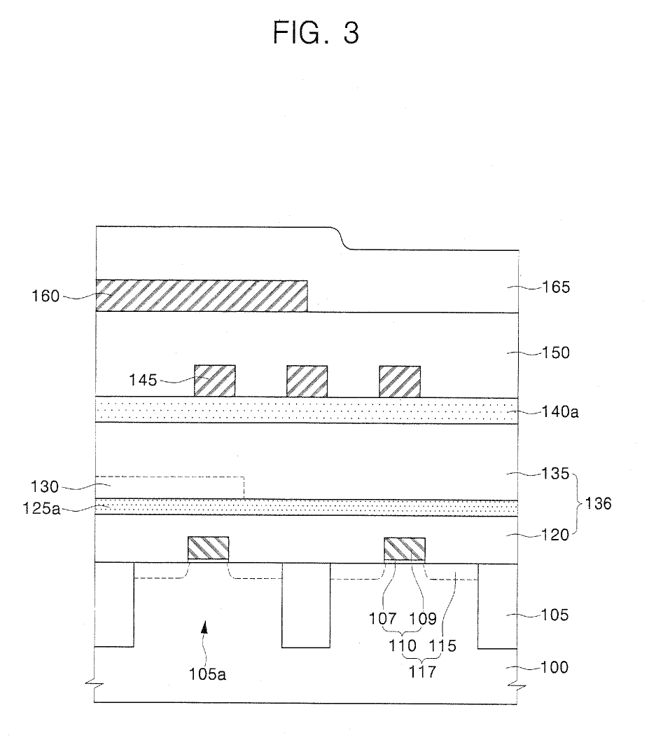

Referring to FIG. 3, a conductive pattern 145 is formed on the substrate having the thermally-treated hydrogen source layer 140a, which may be a lower metal interconnection formed using a metal material to form a metal interconnection such as aluminum. An inter-metal insulating layer 150 may be formed on the substrate having the conductive pattern 145. The inter-metal insulating layer 150 may be formed of a silicon oxide layer, for example. An upper metal interconnection 160 may be formed on the substrate having the inter-metal insulating layer 150. The upper metal interconnection 160 may be formed of a metal material layer such as an aluminum layer. A passivation layer 165 may be formed on the substrate having the upper metal interconnection 160.

As a result of this structure, since the hydrogen source layer 140 is formed and the thermal annealing process 143 is performed before the conductive pattern, in this case the lower metal interconnection 145, is formed, the diffusion of the hydrogen inside the hydrogen source layer 140 is not influenced by the lower metal interconnection 145 and the upper metal interconnection 160. Thus, there exists no barrier such as a metal interconnection in a hydrogen path through which the hydrogen from inside the hydrogen source layer 140 is diffused to the surface of the semiconductor substrate 100. During the thermal annealing process 143 then, the hydrogen can reach the interface of the gate insulating layer 107 quite easily. Thus, an interface trap density of the gate insulating layer 107 can be significantly reduced. As a result, the leakage current characteristics of the MOS transistor 117 can be improved. Further, since the thermal annealing process 143 is performed before the lower metal interconnection 145 is formed in order to improve the leakage current characteristics of the MOS transistor 117, a thermal stress, which may act on the lower metal interconnection 145 and the upper metal interconnection 160, can be minimized. Therefore, a reliability of a semiconductor device can be improved.

As described above, according to an embodiment, the hydrogen inside the hydrogen source layer can be diffused to the surface of the semiconductor substrate, that is, the interface of the gate insulating layer, by forming the hydrogen source layer before forming the conductive pattern such as the lower metal interconnection, and performing a thermal annealing process on the hydrogen source layer. As such, since the hydrogen source layer is formed and thermally-annealing treated before the lower metal interconnection is formed, barriers, which may exist in a path through which the hydrogen atoms from inside the hydrogen source layer are diffused to the surface of the semiconductor substrate, can be significantly reduced. Therefore, since the amount of the hydrogen atoms supplied to the interface of the gate insulating layer of the MOS transistor can be increased, the leakage current characteristics of the MOS transistor can be improved. As a result, a performance of a semiconductor device can be improved.

What is claimed is:

1. A method of fabricating a semiconductor device comprising:
preparing a semiconductor substrate;
forming an interlayer insulating layer on the semiconductor substrate;
forming a hydrogen source layer on the substrate having the interlayer insulating layer;
performing a thermal annealing process on the substrate having the hydrogen source layer so that hydrogen inside the hydrogen source layer is diffused to a surface of the semiconductor substrate; and
forming a conductive pattern on the substrate having the thermally-treated hydrogen source layer.

2. The method according to claim 1, wherein the hydrogen source layer is formed of an insulating layer including hydrogen.

3. The method according to claim 1, wherein the hydrogen source layer comprises a silicon nitride layer.

4. The method according to claim 3, wherein the silicon nitride layer is formed of a PECVD nitride layer.

5. The method according to claim 1, wherein the thermal annealing process is performed at a temperature of about 350° C. to about 500° C.

6. The method according to claim 1, wherein the thermal annealing process is performed for a time of about 30 min. to about 300 min.

7. The method according to claim 1, wherein the thermal annealing process is performed using an ambient gas comprising at least one of nitrogen and hydrogen.

8. The method according to claim 1, wherein the conductive pattern is a metal interconnection.

9. A method of fabricating a semiconductor device comprising:
preparing a semiconductor substrate;
forming a MOS transistor on the semiconductor substrate;
forming an interlayer insulating layer on the substrate having the MOS transistor;
forming a hydrogen source layer on the interlayer insulating layer;
performing a thermal annealing process on the substrate having the hydrogen source layer so that hydrogen inside the hydrogen source layer is diffused to a surface of the semiconductor substrate; and
forming a lower metal interconnection on the substrate having the hydrogen source layer.

10. The method according to claim 9, wherein the hydrogen source layer comprises an insulating layer including hydrogen.

11. The method according to claim 9, wherein the hydrogen source layer comprises a silicon nitride layer.

12. The method according to claim 11, wherein the silicon nitride layer is formed of a PECVD nitride layer.

13. The method according to claim 9, wherein the thermal annealing process is performed at a temperature of about 350° C. to about 500° C.

14. The method according to claim 9, wherein the thermal annealing process is performed for a time of about 30 min. to about 300 min.

15. The method according to claim 9, wherein the thermal annealing process is performed using an ambient gas comprising at least one of nitrogen and hydrogen.

16. The method according to claim 9, wherein the forming of the interlayer insulating layer comprises:
forming a lower interlayer insulating layer on the substrate having the MOS transistor; and
forming an upper interlayer insulating layer over the lower interlayer insulating layer.

17. The method according to claim 16, before forming the upper interlayer insulating layer, the method further comprising forming a lower hydrogen source layer on the lower interlayer insulating layer, in which hydrogen inside the lower hydrogen source layer is diffused to a surface of the semiconductor substrate during the thermal annealing process.

18. The method according to claim 17, wherein the lower hydrogen source layer comprises an insulating layer including hydrogen.

19. The method according to claim 18, after forming the lower hydrogen source layer and after performing the thermal annealing process, the method further comprising forming a conductive line on the hydrogen source layer.

20. The method according to claim 17, after forming the lower hydrogen source layer, the method further comprising forming a conductive line on the substrate having the lower hydrogen source layer.

21. The method according to claim 9, further comprising:
forming an inter-metal insulating layer over the lower metal interconnection;
forming an upper metal interconnection over the inter-metal insulating layer; and
forming a passivation layer over the upper metal interconnection.
